(19) United States
(12) Patent Application Publication
(10) Pub. No.: US 2023/0253923 A1
(43) Pub. Date: Aug. 10, 2023

(54) ADAPTIVE WIRELESS CONFIGURATION BASED ON INPUT POWER

(71) Applicant: Meta Platforms Technologies, LLC, Menlo Park, CA (US)

(72) Inventors: Qiuming LI, Palo Alto, CA (US); Bo ZHANG, San Jose, CA (US); Wooram CHOI, Pleasanton, CA (US)

(21) Appl. No.: 17/831,886

(22) Filed: Jun. 3, 2022

Related U.S. Application Data
(60) Provisional application No. 63/307,829, filed on Feb. 8, 2022.

(51) Int. Cl. H03F 1/02; H03F 3/19

(52) U.S. Cl. CPC H03F 1/0216; H03F 3/19; H03F 2200/294; H03F 2200/451

(57) ABSTRACT

Disclosed herein are related to systems and methods for adaptively configuring various components of a wireless device. In one aspect, the wireless device includes a first low noise amplifier, a second low noise amplifier, and an attenuator coupled between the first low noise amplifier and the second low noise amplifier. In one aspect, the wireless device includes one or more processors configured to determine an input power level at the first low noise amplifier. In one aspect, the one or more processors are configured to determine a group of configurations of the first low noise amplifier, the attenuator, and the second low noise amplifier, according to the determined input power level at the first low noise amplifier. In one aspect, the one or more processors are configured to set the first low noise amplifier, the attenuator, and the second low noise amplifier, according to the determined group of configurations.

### CROSS REFERENCE TO RELATED APPLICATION

This application claims priority to U.S. Provisional Patent Application No. 63/307,829 filed on Feb. 8, 2022, which is incorporated by reference herein in its entirety.

### FIELD OF DISCLOSURE

The present disclosure is generally related to wireless communication, including but not limited to adaptively configuring various components of a wireless device.

### BACKGROUND

Wireless devices may communicate with each other through a wireless medium (e.g., air). Each wireless device may include a transmitter to transmit a wireless signal, and a receiver to receive a wireless signal. A transmitter of a first wireless device may upconvert data for transmission at a baseband frequency to a radio frequency (RF) to generate a wireless signal, and transmit the wireless signal. A receiver of a second wireless device may receive the wireless signal at the RF, and downconvert the wireless signal to the baseband frequency to extract or obtain the data.

### SUMMARY

Various embodiments disclosed herein are related to a device for wireless communication. In some embodiments, the device includes a first low noise amplifier, a second low noise amplifier, and an attenuator coupled between the first low noise amplifier and the second low noise amplifier. In some embodiments, the device includes one or more processors configured to determine an input power level at the first low noise amplifier. In some embodiments, the one or more processors are configured to determine a group of configurations of the first low noise amplifier, the attenuator, and the second low noise amplifier, according to the determined input power level at the first low noise amplifier. In some embodiments, the one or more processors are configured to set the first low noise amplifier, the attenuator, and the second low noise amplifier, according to the determined group of configurations.

In some embodiments, the one or more processors are configured to obtain a table including a plurality of groups of configurations of the first low noise amplifier, the attenuator, and the second low noise amplifier. Each group of configurations of the plurality of groups of configurations may be associated with a corresponding input power level. In some embodiments, the one or more processors are configured to apply the determined input power level to the table to determine the group of configurations associated with the input power level.

In some embodiments, the first low noise amplifier is a first integrated circuit. In some embodiments, the second low noise amplifier is a second integrated circuit. In some embodiments, the second low noise amplifier is an integrated low noise amplifier of a transceiver. In some embodiments, the first low noise amplifier is an off-chip low noise amplifier.

In some embodiments, the one or more processors are configured to set the first low noise amplifier to amplify an input signal of the first low noise amplifier by a first gain, according to a first configuration of the group of configurations. In some embodiments, the one or more processors are configured to set the attenuator to apply an attenuation to a first output signal of the first low noise amplifier, according to a second configuration of the group of configurations. In some embodiments, the one or more processors are configured to set the second low noise amplifier to amplify a second output signal of the attenuator by a second gain, according to a third configuration of the group of configurations.

In some embodiments, the attenuator comprises a gain counterpoise, which may include an adjustable attenuator, a chip attenuator, a resistor network or other device. In some embodiments, the attenuator includes an adjustable attenuator, a chip attenuator, a resistor network, or a bandpass filter between the first low noise amplifier and the second low noise amplifier.

Various embodiments disclosed herein are related to a method of configuring a device for wireless communication. In some embodiments, the method includes determining, by one or more processors, an input power level at a first low noise amplifier. In some embodiments, an attenuator is coupled between the first low noise amplifier and a second low noise amplifier. In some embodiments, the method includes determining, by the one or more processors, a group of configurations of the first low noise amplifier, the attenuator, and the second low noise amplifier, and, according to the determined input power level at the first low noise amplifier. In some embodiments, the method includes setting, by the one or more processors, the first low noise amplifier, the attenuator, and the second low noise amplifier, according to the determined group of configurations.

In some embodiments, the method includes obtaining, by the one or more processors, a table including a plurality of groups of configurations of the first low noise amplifier, the attenuator, and the second low noise amplifier. Each group of configurations of the plurality of groups of configurations may be associated with a corresponding input power level. In some embodiments, the method includes applying, by the one or more processors, the determined input power level to the table to determine the group of configurations associated with the input power level.

In some embodiments, the first low noise amplifier is a first integrated circuit. In some embodiments, the second low noise amplifier is a second integrated circuit. In some embodiments, the second low noise amplifier is an integrated low noise amplifier of a transceiver. In some embodiments, the first low noise amplifier is an off-chip low noise amplifier.

In some embodiments, setting, by the one or more processors, the first low noise amplifier, the attenuator, and the second low noise amplifier includes: setting, by the one or more processors, the first low noise amplifier to amplify an input signal of the first low noise amplifier by a first gain, according to a first configuration of the group of configurations, setting, by the one or more processors, the attenuator to apply an attenuation to a first output signal of the first low noise amplifier, according to a second configuration of the group of configurations, and setting, by the one or more processors, the second low noise amplifier to amplify a second output signal of the attenuator by a second gain, according to a third configuration of the group of configurations.

In some embodiments, the attenuator includes an adjustable attenuator, a chip attenuator, a resistor network, or a bandpass filter between the first low noise amplifier and the second low noise amplifier.

Various embodiments disclosed herein are related to a non-transitory computer readable medium for wireless communication. In some embodiments, the non-transitory computer readable medium stores instructions when executed by one or more processors cause the one or more processors to determine an input power level at a first low noise amplifier. In some embodiments, an attenuator is coupled between the first low noise amplifier and a second low noise amplifier. In some embodiments, the non-transitory computer readable medium stores instructions when executed by the one or more processors cause the one or more processors to determine a group of configurations of the first low noise amplifier, the attenuator, and the second low noise amplifier, according to the determined input power level at the first low noise amplifier. In some embodiments, the non-transitory computer readable medium stores instructions when executed by the one or more processors cause the one or more processors to set the first low noise amplifier, the attenuator, and the second low noise amplifier, according to the determined group of configurations.

In some embodiments, the non-transitory computer readable medium stores instructions when executed by the one or more processors cause the one or more processors to obtain a table including a plurality of groups of configurations of the first low noise amplifier, the attenuator, and the second low noise amplifier. Each group of configurations of the plurality of groups of configurations may be associated with a corresponding input power level. In some embodiments, the non-transitory computer readable medium stores instructions when executed by the one or more processors cause the one or more processors to apply the determined input power level to the table to determine the group of configurations associated with the input power level.

In some embodiments, the first low noise amplifier is a first integrated circuit. In some embodiments, the second low noise amplifier is a second integrated circuit. In some embodiments, the second low noise amplifier is an integrated low noise amplifier of a transceiver. In some embodiments, the first low noise amplifier is an off-chip low noise amplifier. In some embodiments, the attenuator is an adjustable attenuator.

In some embodiments, the instructions when executed by the one or more processors that cause the one or more processors to set the first low noise amplifier, the attenuator, and the second low noise amplifier include instructions when executed by the one or more processors cause the one or more processors to: set the first low noise amplifier to amplify an input signal of the first low noise amplifier by a first gain, according to a first configuration of the group of configurations, set the attenuator to apply an attenuation to a first output signal of the first low noise amplifier, according to a second configuration of the group of configurations, and set the second low noise amplifier to amplify a second output signal of the attenuator by a second gain, according to a third configuration of the group of configurations.

### BRIEF DESCRIPTION OF THE DRAWINGS

The accompanying drawings are not intended to be drawn to scale. Like reference numbers and designations in the various drawings indicate like elements. For purposes of clarity, not every component can be labeled in every drawing.

FIG. 1 is a diagram of an example wireless communication system, according to an example implementation of the present disclosure.

FIG. 2 is a diagram of a wireless device, according to an example implementation of the present disclosure.

FIG. 3 is a table of different configurations for corresponding input power levels, according to an example implementation of the present disclosure.

FIG. 4 is a flowchart showing a process of adaptively configuring a wireless device based on input power level, according to an example implementation of the present disclosure.

### DETAILED DESCRIPTION

Before turning to the figures, which illustrate certain embodiments in detail, it should be understood that the present disclosure is not limited to the details or methodology set forth in the description or illustrated in the figures. It should also be understood that the terminology used herein is for the purpose of description only and should not be regarded as limiting.

Disclosed herein are related to adaptively configuring various components of a wireless device. In one aspect, the wireless device includes a first low noise amplifier (LNA), a second LNA, and an attenuator coupled between the first LNA and the second LNA. In one aspect, the one or more processors are configured to determine a group (e.g., collection, set) of configurations of/for the first low noise amplifier, the attenuator, and the second low noise amplifier, according to the determined input power level at the first low noise amplifier. Each configuration of the group of configurations may indicate a bias/absolute/offset/relative setting or a control parameter for a corresponding one of the first low noise amplifier, the attenuator, and the second low noise amplifier to provide a certain gain or attenuation. In one aspect, the one or more processors are configured to set the first LNA, the attenuator, and the second LNA, according to the determined group of configurations.

In one aspect, the one or more processors may obtain a table including a plurality of groups of configurations of the first LNA, the attenuator, and the second LNA. Each group of configurations of the plurality of groups of configurations may be associated with a corresponding power level (e.g., input power level of the first LNA). In one embodiment, the wireless device includes a storage that stores the table, and the one or more processors may obtain or retrieve the table from the storage. In one embodiment, the one or more processors can store or retain the table internally. The one or more processors may apply the determined input power level to the table to determine (e.g., identify, select) the group of configurations associated with (e.g., corresponding/assigned to) the input power level.

Advantageously, various components of the wireless device including the first LNA, the attenuator, and the second LNA can be adaptively/dynamically configured. In one aspect, implementing two stage LNAs or cascaded LNAs is subject to various considerations. For example, two stage LNAs may be set or configured to have a high gain (e.g., over 40 dB˜100 dB) to provide a high sensitivity with low noise figure. However, two stage LNAs with excessive gain may suffer from a transmission leakage and/or low linearity, and may fail blocking tests. Meanwhile, reducing a gain of one or more LNAs may be less susceptible to the transmission leakage, may improve linearity, and may obviate failing blocking tests. However, reducing a gain of one or more LNAs may degrade sensitivity and/or noise figure. In one aspect, the wireless device includes an attenuator (e.g., gain counterpoise device/circuit) coupled (e.g., directly or indirectly) between the first LNA and the second LNA, where configurations of the first LNA, the attenuator, and the second LNA can be adaptively adjusted/modified/changed, according to input power level detected. For example, the attenuator may provide a low attenuation and the LNAs may provide high gains for a low input power level detected, to achieve high sensitivity and low noise figure. For example, the attenuator may provide a high attenuation and the LNAs may provide low gains for a high input power level detected, to achieve high linearity. Hence, by adaptively configuring (e.g., the gain and/or other states/settings of) the first LNA, the attenuator, and the second LNA according to the input power level, the wireless device can achieve high sensitivity and high linearity, while reducing effects due to transmitter leakage and/or obviating blocking test failures.

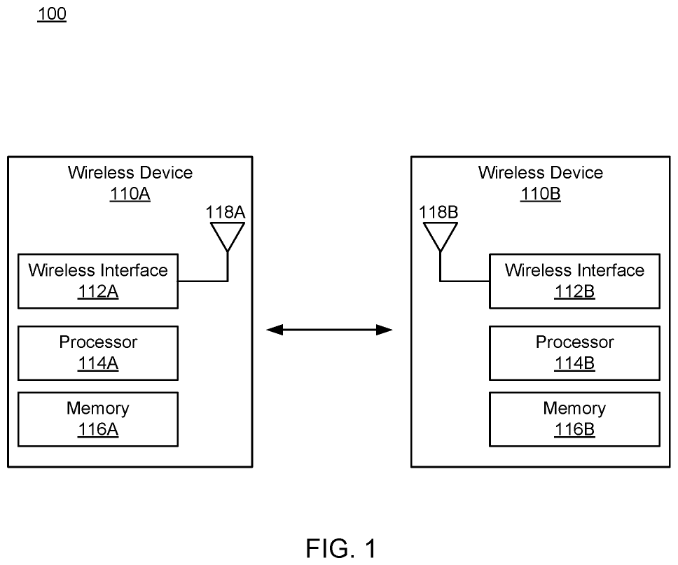

FIG. 1 is a diagram of an example wireless communication system 100, according to an example implementation of the present disclosure. In some embodiments, the wireless communication system 100 includes wireless devices 110A, 110B. Each of the wireless devices 110A, 110B may be any device that can communicate through a wireless link. Each of the wireless devices 110A, 110B may be an access point, base station, router, smart phone, laptop, tablet PC, etc. The wireless link may be a cellular communication link (e.g., 3G, 4G, 5G), Wi-Fi communication link, Bluetooth communication link, 60 GHz communication link, or any communication link. In some embodiments, the wireless communication system 100 includes more wireless devices than shown in FIG. 1.

In some embodiments, the wireless device 110A includes a wireless interface 112A, a processor 114A, a memory device 116A, and one or more antennas 118A. Similarly, the wireless device 110B includes a wireless interface 112B, a processor 114B, a memory device 116B, and one or more antennas 118B. These components may be embodied as hardware, software, firmware, or a combination thereof. In some embodiments, the wireless devices 110A, 110B include more, fewer, or different components than shown in FIG. 1. For example, the wireless devices 110A, 110B may each include an electronic display and/or an input device. For example, the wireless devices 110A, 110B may each include one or more additional antennas 118 than shown in FIG. 1.

The antenna 118 may be a component that receives a radio frequency (RF) signal and/or transmits a RF signal through a wireless medium (e.g., air). The RF signal may be at a frequency between 200 MHz to 100 GHz. The RF signal may have packets, symbols, or frames corresponding to data for communication. The antenna 118 may be a dipole antenna, a patch antenna, a ring antenna, a slot antenna, or any suitable antenna for wireless communication. In one aspect, a single antenna 118 is utilized for both transmitting a RF signal and receiving a RF signal. In one aspect, different antennas 118 are utilized for transmitting the RF signal and receiving the RF signal. In one aspect, multiple antennas 118 are utilized to support multiple-in, multiple-out (MIMO) communication.

The wireless interface 112 includes or is embodied as a transceiver for transmitting and receiving RF signals through one or more antennas 118. In one configuration, the wireless interface 112 is coupled to one or more antennas 118. In one aspect, the wireless interface 112 may receive the RF signal at the RF received through an antenna 118, and downconvert the RF signal to a baseband frequency (e.g., 0˜1 GHz). The wireless interface 112 may provide the downconverted signal to the processor 114. In one aspect, the wireless interface 112 may receive a baseband signal for transmission at a baseband frequency from the processor 114, and upconvert the baseband signal to generate a RF signal. The wireless interface 112 may transmit the RF signal through the antenna 118.

The processor 114 is a component that processes data. The processor 114 may be embodied as field programmable gate array (FPGA), application specific integrated circuit (ASIC), a logic circuit, etc. The processor 114 may obtain instructions from the memory device 116, and executes the instructions. In one aspect, the processor 114 may receive downconverted data at the baseband frequency from the wireless interface 112, and decode or process the downconverted data. For example, the processor 114 may generate audio data or image data according to the downconverted data, and present an audio indicated by the audio data and/or an image indicated by the image data to a user of the wireless device 110. In one aspect, the processor 114 may generate or obtain data for transmission at the baseband frequency, and encode or process the data. For example, the processor 114 may encode or process image data or audio data at the baseband frequency, and provide the encoded or processed data to the wireless interface 112 for transmission.

The memory device 116 is a component that stores data. The memory device 116 may be embodied as random access memory (RAM), flash memory, read only memory (ROM), erasable programmable read-only memory (EPROM), electrically erasable programmable read-only memory (EEPROM), registers, a hard disk, a removable disk, a CD-ROM, or any device capable for storing data. The memory device 116 may be embodied as a non-transitory computer readable medium storing instructions executable by the processor 114 to perform various functions of the wireless device 110 disclosed herein. In some embodiments, the memory device 116 and the processor 114 are integrated as a single component.

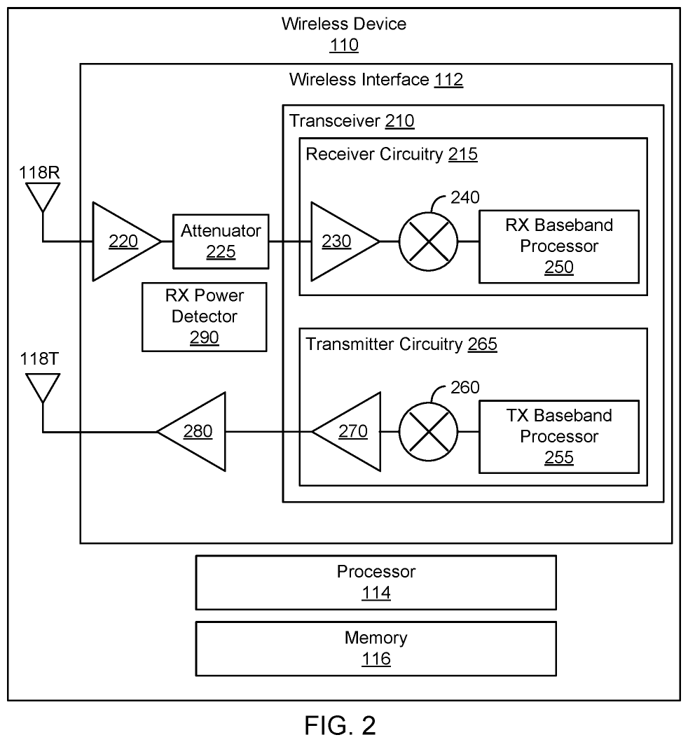

FIG. 2 is a diagram of the wireless device 110, according to an example implementation of the present disclosure. In some embodiments, the wireless device 110 includes antennas 118R, 118T, the wireless interface 112, the processor 114, and/or the memory device 116. These components may operate together to receive or transmit RF signals at a RF. In some embodiments, the wireless device 110 includes more, fewer, or different components than shown in FIG. 2. For example, the wireless device 110 includes more antennas than shown in FIG. 2.

In some embodiments, the antenna 118R may be a component that receives a RF signal through a wireless medium, and the antenna 118T may be a component that transmits a RF signal through the wireless medium. The RF signal may be at a frequency between 200 MHz to 100 GHz. The RF signal may have packets, symbols, or frames corresponding to data for communication. The antennas 118R, 118T may be dipole antennas, patch antennas, ring antennas, slot antennas, or any suitable antennas for wireless communication. In some embodiments, the antennas 118R, 118T may have the same structural configuration (e.g., shape, size, dimension), and may be tuned for the same frequency band. In some embodiments, the antennas 118R, 118T may have different structural configurations, and may be tuned for the different frequency bands. In some embodiments, a single antenna 118 is implemented instead of two separate antennas 118R, 118T to receive and transmit.

In some embodiments, the wireless interface 112 is a component that transmits and receives RF signals through one or more antennas 118R, 118T. In one aspect, the wireless interface 112 includes a LNA 220, an attenuator 225, a transceiver 210, a power amplifier 280, and/or a RX power detector 290 (may be also referred to as “a downlink power detector 290”). In some embodiments, the transceiver 210 includes a receiver circuitry 215 and a transmitter circuitry 265. The receiver circuitry 215 and the transmitter circuitry 265 may be embodied as a single integrated circuit. Alternatively, in some embodiments, the receiver circuitry 215 and the transmitter circuitry 265 may be embodied as separate integrated circuits. In some embodiments, the transceiver 210, the processor 114, and the memory device 116 may be embodied as a single integrated circuit. Alternatively, in some embodiments, the transceiver 210, the processor 114, and the memory device 116 may be embodied as separate integrated circuits. In some embodiments, the wireless interface 112 includes more, fewer, or different components than shown in FIG. 2. For example, the wireless interface 112 includes one or more additional transceivers, additional amplifiers, filters, or any combination of them.

In one aspect, the LNA 220, the attenuator 225, and the receiver circuitry 215 may operate together to receive an RF signal through the antenna 118R. In some embodiments, the receiver circuitry 215 includes a LNA 230, a mixer 240 (also referred to as a demodulator 240), and a receive (RX) baseband processor 250. In some embodiments, the receiver circuitry 215 includes more, fewer, or different components than shown in FIG. 2. For example, the receiver circuitry 215 includes additional amplifiers, mixers, and/or filters. In one aspect, the LNA 220, the attenuator 225, and the transceiver 210 are implemented as separate components, and may be manufactured by different entities. Hence, the LNA 220 may be implemented as an off-chip or external LNA, and the LNA 230 may be implemented as an on-chip/integrated LNA with other components (e.g., receiver circuitry 215 and the transmitter circuitry 265) of the transceiver 210.

In one configuration, the LNA 220 includes an input coupled (e.g., directly or indirectly) to the antenna 118R, and an output coupled (e.g., directly or indirectly) to the attenuator 225. In one configuration, the attenuator 225 includes an output coupled (e.g., directly or indirectly) to an input of the LNA 230. Hence, the attenuator 225 may be coupled between the LNA 220 and the LNA 230. In one configuration, the LNA 230 includes an output coupled (e.g., directly or indirectly) to an input of the mixer 240. In one configuration, the mixer 240 includes an output coupled to an input of the RX baseband processor 250. In one configuration, the RX baseband processor 250 includes an output coupled to the processor 114.

In this configuration, the LNA 220 may receive a RF signal at a RF through the antenna 118R, and can amplify the received RF signal to generate a first amplified RF RX signal. The LNA 220 may provide the first amplified RF RX signal to the attenuator 225. The attenuator 225 may include a resister network or a filter (e.g., bandpass filter). The attenuator 225 may be an adjustable attenuator. The attenuator 225 may be a device or circuitry for counterpoising/balancing/interfacing/matching/transitioning gain and/or other properties between first and second circuitries (e.g., LNA 220 and LNA 230) respectively connected to the attenuator's input and output. The attenuator 225 may attenuate and/or filter the first amplified

RF RX signal from the LNA 220 for a particular frequency band, and can provide the attenuated signal to the LNA 230. The LNA 230 may receive the attenuated signal at a RF from the attenuator 225, and can amplify the received attenuated RF signal to generate or obtain a second amplified RF RX signal. The LNA 230 may provide the second amplified RF RX signal to the mixer 240. The mixer 240 may downconvert the second amplified RF RX signal to a baseband frequency (e.g., 0˜1 GHz) to generate or obtain a downconverted signal (also referred to as a RX baseband signal). The mixer 240 may provide the downconverted signal to the RX baseband processor 250. The RX baseband processor 250 may perform various processes to obtain or extract content data (e.g., audio data, image data, text data, etc.) from the downconverted data. For example, the RX baseband processor 250 may perform filtering, decoding, decompression, error correction, etc. to the downconverted data to obtain or extract the content data. The RX baseband processor 250 may provide the obtained or extracted content data to the processor 114.

In one aspect, the power amplifier 280 and the transmitter circuitry 265 may operate together to transmit an RF signal through the antenna 118T. In some embodiments, the transmitter circuitry 265 includes a preamplifier 270, a mixer 260 (also referred to as a modulator 260), and a transmit (TX) baseband processor 255. In some embodiments, the transmitter circuitry 265 includes more, fewer, or different components than shown in FIG. 2. For example, the transmitter circuitry 265 may include additional amplifiers, mixers, and/or filters, or may omit the preamplifier 270. In one aspect, the power amplifier 280 and the transceiver 210 are implemented as separate components, and may be manufactured by different entities.

In one configuration, the TX baseband processor 255 includes an input coupled to the processor 114 and an output coupled to an input of the mixer 260. In one configuration, the mixer 260 includes an output coupled to an input of the preamplifier 270. In one configuration, the preamplifier 270 includes an output coupled to an input of the power amplifier 280. In one configuration, the power amplifier 280 includes an output coupled to the antenna 118T.

In this configuration, the TX baseband processor 255 may receive content data (e.g., audio data, image data, text data, etc.) to transmit from the processor 114, and can perform various processing on the content data. For example, the TX baseband processor 255 may perform filtering, encoding, compression, error correction, etc. to generate or obtain a TX baseband signal. The TX baseband processor 255 may provide the TX baseband signal to the mixer 260. The mixer 260 may receive the TX baseband signal at a baseband frequency, and can upconvert the TX baseband signal to generate an upconverted signal. The mixer 260 may provide the upconverted signal at a RF to the preamplifier 270. The preamplifier 270 may receive the upconverted signal from the mixer 260 and perform a first amplification on the upconverted signal from the mixer 260 to generate a first amplified RF TX signal. The preamplifier 270 may provide the first amplified RF TX signal to the power amplifier 280. The power amplifier 280 may perform a second amplification on the first amplified RF TX signal to generate a second amplified RF TX signal. The power amplifier 280 may transmit the second amplified RF TX signal through the antenna 118T.

In some embodiments, the processor 114 is a component that sets or configures operations of the wireless device 110. The processor 114 may be embodied as FPGA, ASIC, or any logic circuit. The processor 114 may include one or more processors or computing units. The processor 114 may execute one or more instructions stored by the memory device 116 or a non-transitory computer readable medium to perform various functions of the processor 114 or the wireless device 110 described herein. In one aspect, the processor 114 may receive content data from the receiver circuitry 215 for reception. In one aspect, the processor 114 may transmit or provide content data to the transmitter circuitry 265 for transmission. In some embodiments, the processor 114, the RX baseband processor 250, and the TX baseband processor 255 may be embodied as a single integrated circuit.

In one aspect, the processor 114 may determine an input power level of an RF signal at the input of the LNA 220. In some embodiments, the RX power detector 290 detects a power level of a signal at an output of the LNA 220, at an output of the attenuator 225, at an output of the LNA 230, or an output of the mixer 240, and generates a power detection signal indicating the detected power level. The processor 114 may receive the power detection signal from the RX power detector 290, and can determine the input (e.g., signal/electrical) power level of the RF signal at the input of the LNA 220, according to the power detection signal. For example, the processor 114 may divide the detected power level by an amount of gain and/or an amount of attenuation applied between the input of the LNA 220 and a node, at which the power level is detected. For example, the RX power detector 290 may detect an amplitude or power of the baseband signal at the output of the mixer 240, and can generate a power detection signal indicating the detected power level. The processor 114 may receive the power detection signal, and can determine (e.g., measure, calculate) the input power level of the RF signal at the input of the LNA 220 by i) dividing the detected power level by gains of the LNA 220, the LNA 230, and the mixer 240, and ii) multiplying by the attenuation/gain of the attenuator 225.

According to the input power level of the RF signal at the input of the LNA 220, the processor 114 may set/apply a group of configurations of the wireless interface 112. For example, the memory device 116 may store a table including a plurality of (candidate) groups of configurations of the LNA 220, the attenuator 225, and the LNA 230. Each of the plurality of groups of configurations may be associated with a corresponding power level. Each configuration of the group of configurations may indicate a bias setting or a control parameter for a corresponding one of the LNA 220, the attenuator 225, and the second LNA 230 to provide a certain gain or attenuation. For example, a first configuration of the group of configurations for a particular input power level indicates a bias setting or a control parameter to cause or configure the first LNA 220 to provide a gain for the particular input power level. For example, a second configuration of the group of configurations for the particular input power level indicates a bias setting or a control parameter to cause or configure the attenuator 225 to provide an attenuation for the particular input power level. For example, a third configuration of the group of configurations of the particular input power level indicates a bias setting or a control parameter to cause or configure the second LNA 230 to provide a gain for the particular input power level. In one embodiment, the processor 114 may obtain or retrieve the table from the memory device 116. In one embodiment, the processor 114 stores or retains the table internally. The processor 114 may apply the determined input power level to the table to determine the group of configurations associated with the input power level. The processor 114 may generate control signals corresponding to the determined group of configurations, and can apply the control signals to the LNA 220, the attenuator 225, and the LNA 230 to set the LNA 220, the attenuator 225, and the LNA 230 according to the determined group of configurations.

Advantageously, various components of the wireless device 110 can be adaptively configured. In one aspect, implementing two stage LNAs 220, 230 or cascaded LNAs 220, 230 is subject to various considerations, for example, when the LNAs 220, 230 are separate integrated circuits designed and implemented by different entities. For example, two stage LNAs 220, 230 may be set or configured to have a high gain to provide a high sensitivity with low noise figure. However, two stage LNAs 220, 230 with excessive gain may suffer from transmission leakage from a transmitter (e.g., the transmitter circuitry 265 and/or the power amplifier 280) or low linearity, and may fail blocking tests. Meanwhile, reducing a gain of one or more LNAs 220, 230 may be less susceptible to the transmission leakage, may improve linearity, and may obviate failing blocking tests. However, reducing a gain of one or more LNAs 220, 230 may degrade sensitivity and/or low noise figure. In one aspect, the wireless device 110 includes an attenuator 225 coupled between the LNAs 220, 230, where configurations of the LNA 220, the attenuator 225, and the LNA 230 can be adaptively adjusted, according to input power level detected. For example, the attenuator 225 may provide a low attenuation and the LNAs 220, 230 may provide high gains for a low input power level detected to achieve high sensitivity and low noise figure. For example, the attenuator 225 may provide a high attenuation and the LNAs 220, 230 may provide low gains for a high input power level detected to achieve high linearity. Hence, by adaptively configuring the LNA 220, the attenuator 225, and the LNA 230 according to the input power level, the wireless device 110 can achieve high sensitivity and high linearity, while reducing effects due to transmitter leakage and/or obviating blocking test failures.

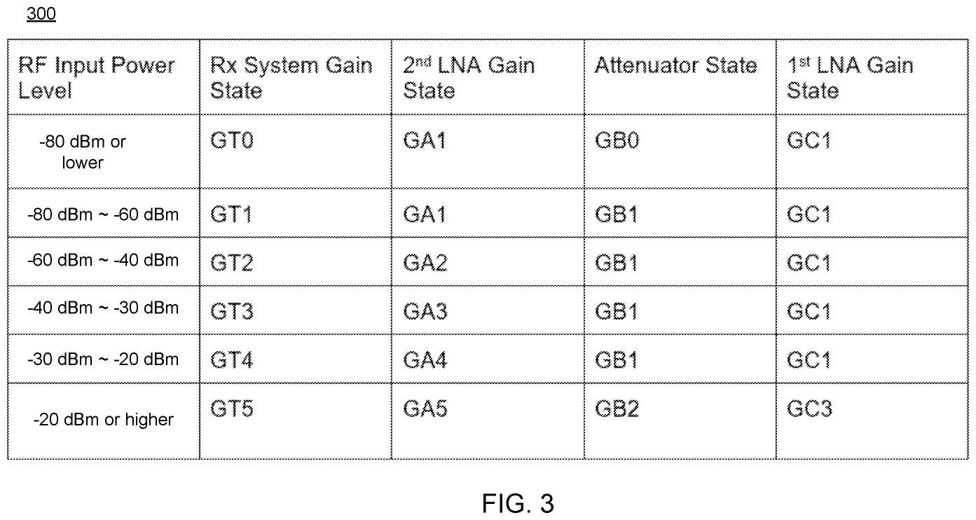

FIG. 3 is a table 300 of different groups of configurations for corresponding input power levels, according to an example implementation of the present disclosure. In one aspect, the table 300 is stored by the memory device 116. In some embodiments, each row of the table 300 includes or corresponds to a group of configurations associated with a corresponding power level. Each configuration of the group of configurations may indicate a bias/offset/relative/absolute setting or a control parameter for a corresponding one of the LNA 220, the attenuator 225, and the LNA 230 to provide a certain gain or attenuation. In one aspect, configurations of the LNA 220, the attenuator 225, and the LNA 230 are determined (e.g., via a calibration and/or characterization process on the wireless device) for a corresponding input power level to optimize sensitivity, noise figure, linearity, etc. For example, configurations GC1-GC3 can indicate bias settings or control parameters of the LNA 220 to set an amount of gain of the LNA 220 in a descending order. For example, configurations GB0-GB2 can indicate bias settings or control parameters of the attenuator 225 to set an amount of attenuation of the attenuator 225 in an ascending order. For example, configurations GA1-GA5 can indicate bias settings or control parameters of the LNA 230 to set an amount of gain of the LNA 230 in a descending order. For example, configurations GT0-GT5 may each indicate or correspond to configurations of the LNA 220, the attenuator 225, and the LNA 230 in the same row. The processor 114 may apply the determined input power level to the table 300 to determine the group of configurations associated with the input power level. For example, the processor 114, the baseband processor 250, and/or the baseband processor 255 may have a separate memory allocation to store the RX switching points or thresholds of the input power level for determining which input level range corresponds to which configuration.

The processor 114, the baseband processor 250, and/or the baseband processor 255 may generate control signals corresponding to the determined group of configurations, and can apply the control signals to the LNA 220, the attenuator 225, and the LNA 230 to set the LNA 220, the attenuator 225, and the LNA 230 according to the determined group of configurations. For example, in response to the detected input power level being between −80 dBm and −60 dBm, the processor 114, the baseband processor 250, and/or the baseband processor 255 may generate one or more control signals corresponding to the configurations GT1, GA1, GB1, GC1, and can apply the one or more control signals to the LNA 220, the attenuator 225, and the LNA 230. For example, in response to the detected input power level being between −60 dBm and −40 dBm, the processor 114, the baseband processor 250, and/or the baseband processor 255 may generate one or more control signals corresponding to the configurations GT2, GA2, GB1, GC1, and can apply the one or more control signals to the LNA 220, the attenuator 225, and the LNA 230. Accordingly, the wireless device 110 may be adaptively configured to satisfy various considerations such as sensitivity, noise figure, linearity for a wide range of input power level.

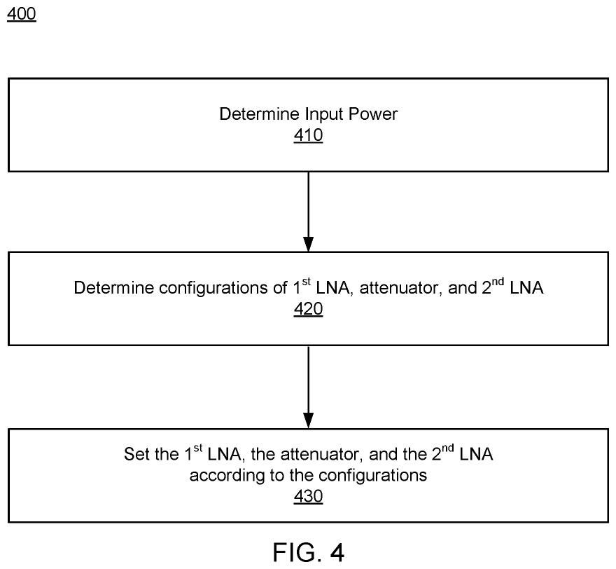

FIG. 4 is a flowchart showing a process 400 of adaptively configuring a wireless device 110 based on input power level detected, according to an example implementation of the present disclosure. In some embodiments, the process 400 is performed by the wireless device 110. In some embodiments, the process 400 is performed by other entities. In some embodiments, the process 400 includes more, fewer, or different steps than shown in FIG. 4.

In one approach, the wireless device 110 determines 410 an input power level at an input of a LNA 220. In one approach, the RX power detector 290 detects a power level of a signal at an output of the LNA 220, at an output of the attenuator 225, at an output of the LNA 230, or an output of the mixer 240, and can generate a power detection signal indicating the detected power level. The processor 114 may receive the power detection signal, and can determine the input power level of the RF signal at the input of the LNA 220, according to the power detection signal. For example, the processor 114 may divide the detected power level by an amount of gain and/or an amount of attenuation applied between the input of the LNA 220 and a node, at which the power level is detected. For example, the RX power detector 290 may detect an amplitude or power of the baseband signal at the output of the mixer 240, and can generate a power detection signal indicating the detected power level. The processor 114 may receive the power detection signal, and can determine the input power level of the RF signal at the input of the LNA 220 by i) dividing the detected power level by gains of the LNA 220, the LNA 230, the mixer 240, and ii) multiplying by the attenuation of the attenuator 225.

In one approach, the wireless device 110 determines 420 a group of configurations of the LNA 220, the attenuator 225, and the LNA 230, according to the determined input power level. For example, the memory device 116 may store a table including a plurality of groups of configurations of the LNA 220, the attenuator 225, and the LNA 230. Each of the plurality of groups of configurations may be associated with a corresponding power level. Each configuration of the group of configurations may indicate a bias setting or a control parameter for a corresponding one of the LNA 220, the attenuator 225, and the second LNA 230 to provide a certain gain or attenuation. In one embodiment, the processor 114 may obtain or retrieve the table from the memory device 116. In one embodiment, the processor 114 stores or retains the table. The processor 114 may apply the determined input power level to the table to determine the group of configurations associated with the input power level.

In one approach, the wireless device 110 sets 430 the LNA 220, the attenuator 225 and the LNA 230, according to the determined group of configurations. The processor 114, the baseband processor 250, and/or the baseband processor 255 may generate one or more control signals corresponding to the determined group of configurations, and apply the one or more control signals to the LNA 220, the attenuator 225 and the LNA 230.

Having now described some illustrative implementations, it is apparent that the foregoing is illustrative and not limiting, having been presented by way of example. In particular, although many of the examples presented herein involve specific combinations of method acts or system elements, those acts and those elements can be combined in other ways to accomplish the same objectives. Acts, elements and features discussed in connection with one implementation are not intended to be excluded from a similar role in other implementations or implementations.

The hardware and data processing components used to implement the various processes, operations, illustrative logics, logical blocks, modules and circuits described in connection with the embodiments disclosed herein may be implemented or performed with a general purpose single- or multi-chip processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some embodiments, particular processes and methods may be performed by circuitry that is specific to a given function. The memory (e.g., memory, memory unit, storage device, etc.) may include one or more devices (e.g., RAM, ROM, Flash memory, hard disk storage, etc.) for storing data and/or computer code for completing or facilitating the various processes, layers and modules described in the present disclosure. The memory may be or include volatile memory or non-volatile memory, and may include database components, object code components, script components, or any other type of information structure for supporting the various activities and information structures described in the present disclosure. According to an exemplary embodiment, the memory is communicably connected to the processor via a processing circuit and includes computer code for executing (e.g., by the processing circuit and/or the processor) the one or more processes described herein.

The present disclosure contemplates methods, systems and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular can also embrace implementations including a plurality of these elements, and any references in plural to any implementation or element or act herein can also embrace implementations including only a single element. References in the singular or plural form are not intended to limit the presently disclosed systems or methods, their components, acts, or elements to single or plural configurations. References to any act or element being based on any information, act or element can include implementations where the act or element is based at least in part on any information, act, or element.

Any implementation disclosed herein can be combined with any other implementation or embodiment, and references to “an implementation,” “some implementations,” “one implementation” or the like are not necessarily mutually exclusive and are intended to indicate that a particular feature, structure, or characteristic described in connection with the implementation can be included in at least one implementation or embodiment. Such terms as used herein are not necessarily all referring to the same implementation. Any implementation can be combined with any other implementation, inclusively or exclusively, in any manner consistent with the aspects and implementations disclosed herein.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Systems and methods described herein may be embodied in other specific forms without departing from the characteristics thereof. References to “approximately,” “about” “substantially” or other terms of degree include variations of +/−10% from the given measurement, unit, or range unless explicitly indicated otherwise. Coupled elements can be electrically, mechanically, or physically coupled with one another directly or with intervening elements. Scope of the systems and methods described herein is thus indicated by the appended claims, rather than the foregoing description, and changes that come within the meaning and range of equivalency of the claims are embraced therein.

The term “coupled” and variations thereof includes the joining of two members directly or indirectly to one another. Such joining may be stationary (e.g., permanent or fixed) or moveable (e.g., removable or releasable). Such joining may be achieved with the two members coupled directly with or to each other, with the two members coupled with each other using a separate intervening member and any additional intermediate members coupled with one another, or with the two members coupled with each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

References to “or” can be construed as inclusive so that any terms described using “or” can indicate any of a single, more than one, and all of the described terms. A reference to “at least one of ‘A’ and ‘B’” can include only ‘A’, only ‘B’, as well as both ‘A’ and ‘B’. Such references used in conjunction with “comprising” or other open terminology can include additional items.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

References herein to the positions of elements (e.g., “top,” “bottom,” “above,” “below”) are merely used to describe the orientation of various elements in the FIGURES. The orientation of various elements may differ according to other exemplary embodiments, and that such variations are intended to be encompassed by the present disclosure.

What is claimed is:

1. A device comprising:
a first low noise amplifier;
a second low noise amplifier;
an attenuator coupled between the first low noise amplifier and the second low noise amplifier; and
one or more processors configured to:
determine an input power level at the first low noise amplifier,
determine a group of configurations of the first low noise amplifier, the attenuator and the second low noise amplifier, according to the determined input power level at the first low noise amplifier, and
set the first low noise amplifier, the attenuator, and the second low noise amplifier, according to the determined group of configurations.

2. The device of claim 1,
wherein the one or more processors are configured to obtain a table including a plurality of groups of configurations of the first low noise amplifier, the attenuator, and the second low noise amplifier, each group of configurations of the plurality of groups of configurations associated with a corresponding input power level,
wherein the one or more processors are configured to apply the determined input power level to the table to determine the group of configurations associated with the input power level.

3. The device of claim 1,
wherein the first low noise amplifier is a first integrated circuit, and
wherein the second low noise amplifier is a second integrated circuit.

4. The device of claim 1,
wherein the second low noise amplifier is an integrated low noise amplifier of a transceiver, and
wherein the first low noise amplifier is an off-chip low noise amplifier.

5. The device of claim 1, wherein the attenuator is an adjustable attenuator.

6. The device of claim 1, wherein the one or more processors are configured to:
set the first low noise amplifier to amplify an input signal of the first low noise amplifier by a first gain, according to a first configuration of the group of configurations,
set the attenuator to apply an attenuation to a first output signal of the first low noise amplifier, according to a second configuration of the group of configurations, and
set the second low noise amplifier to amplify a second output signal of the attenuator by a second gain, according to a third configuration of the group of configurations.

7. The device of claim 1, wherein the attenuator includes an adjustable attenuator, a chip attenuator, a resistor network, or a bandpass filter between the first low noise amplifier and the second low noise amplifier.

8. A method comprising:
determining, by one or more processors, an input power level at a first low noise amplifier, wherein an attenuator is coupled between the first low noise amplifier and a second low noise amplifier;
determining, by the one or more processors, a group of configurations of the first low noise amplifier, the attenuator, the second low noise amplifier, according to the determined input power level at the first low noise amplifier; and
setting, by the one or more processors, the first low noise amplifier, the attenuator, and the second low noise amplifier, according to the determined group of configurations.

9. The method of claim 8, further comprising:
obtaining, by the one or more processors, a table including a plurality of groups of configurations of the first low noise amplifier, the attenuator, and the second low noise amplifier, each group of configurations of the plurality of groups of configurations associated with a corresponding input power level; and
applying, by the one or more processors, the determined input power level to the table to determine the group of configurations associated with the input power level.

10. The method of claim 8,
wherein the first low noise amplifier is a first integrated circuit, and
wherein the second low noise amplifier is a second integrated circuit.

11. The method of claim 8,
wherein the second low noise amplifier is an integrated low noise amplifier of a transceiver, and
wherein the first low noise amplifier is an off-chip low noise amplifier.

12. The method of claim 8, wherein the attenuator is an adjustable attenuator.

13. The method of claim 8, wherein setting, by the one or more processors, the first low noise amplifier, the attenuator, and the second low noise amplifier includes:
setting, by the one or more processors, the first low noise amplifier to amplify an input signal of the first low noise amplifier by a first gain, according to a first configuration of the group of configurations,
setting, by the one or more processors, the attenuator to apply an attenuation to a first output signal of the first low noise amplifier, according to a second configuration of the group of configurations, and
setting, by the one or more processors, the second low noise amplifier to amplify a second output signal of the attenuator by a second gain, according to a third configuration of the group of configurations.

14. The method of claim 8, wherein the attenuator includes an adjustable attenuator, a chip attenuator, a resistor network, or a bandpass filter between the first low noise amplifier and the second low noise amplifier.

15. A non-transitory computer readable medium storing instructions when executed by one or more processors cause the one or more processors to:
determine an input power level at a first low noise amplifier, wherein an attenuator is coupled between the first low noise amplifier and a second low noise amplifier;
determine a group of configurations of the first low noise amplifier, the attenuator, and the second low noise amplifier, according to the determined input power level at the first low noise amplifier; and
set the first low noise amplifier, the attenuator, and the second low noise amplifier, according to the determined group of configurations.

16. The non-transitory computer readable medium of claim 15,
wherein the instructions when executed by the one or more processors cause the one or more processors to obtain a table including a plurality of groups of configurations of the first low noise amplifier, the attenuator, and the second low noise amplifier, each group of configurations of the plurality of groups of configurations associated with a corresponding input power level, and
wherein the instructions when executed by the one or more processors cause the one or more processors to apply the determined input power level to the table to determine the group of configurations associated with the input power level.

17. The non-transitory computer readable medium of claim 15,
wherein the first low noise amplifier is a first integrated circuit, and
wherein the second low noise amplifier is a second integrated circuit.

18. The non-transitory computer readable medium of claim 15,
wherein the second low noise amplifier is an integrated low noise amplifier of a transceiver, and
wherein the first low noise amplifier is an off-chip low noise amplifier.

19. The non-transitory computer readable medium of claim 15, wherein the attenuator is an adjustable attenuator.

20. The non-transitory computer readable medium of claim 15, wherein the instructions when executed by the one or more processors cause the one or more processors to:
set the first low noise amplifier to amplify an input signal of the first low noise amplifier by a first gain, according to a first configuration of the group of configurations,
set the attenuator to apply an attenuation to a first output signal of the first low noise amplifier, according to a second configuration of the group of configurations, and
set the second low noise amplifier to amplify a second output signal of the attenuator by a second gain, according to a third configuration of the group of configurations.
